(19) United States
(12) Patent Application Publication
(10) Pub. No.: US 2004/0201970 A1
(43) Pub. Date: Oct. 14, 2004

(54) Chip interconnection method and apparatus

(75) Inventors: Paul Marlan Harvey, Austin, TX (US); Harm Peter Hofstee, Austin, TX (US); James Allan Kahle, Austin, TX (US); Gordon J. Robbins, Austin, TX (US)

Correspondence Address: Gregory W. Carr, 670 Founders Square, 900 Jackson Street, Dallas, TX, 75202, US

(73) Assignee: International Business Machines Corporation, Armonk, NY

(21) Appl. No.: 10/411,419

(22) Filed: Apr. 10, 2003

(51) Int. Cl. H05K 7/02

(52) U.S. Cl. 361/760

(57) ABSTRACT

Disclosed is an apparatus which shows the use of an inwardly disposed set of C4 type I/O connections to an integrated circuit chip over and above the typical peripherally disposed set of I/O connections which use wire type connections between the chip and other circuitry of a substrate upon which the chip is mounted. The inwardly disposed set of connections may be used to provide a direct connection to an optional ancillary chip having a corresponding set of I/O connection points. Such a construction not only increases the number of possible I/O connections, but additionally increases the bandwidth of communications between the directly connected chips.

### TECHNICAL FIELD

The invention generally relates to increasing the communication bandwidth between electronic chips on a substrate.

### BACKGROUND

Normally, the I/O (input/output) connections or terminals of an integrated circuit chip are located on the peripheral edges of the chip. When such a chip is used on a planar or other substrate, a connection is made from these peripheral I/O terminals to the planar. Typically these connections are accomplished using gold or other metal wires. These wires have a finite amount of resistance, capacitance and inductance. Thus, at times the bandwidth obtainable from these I/O terminals is less than what might be desirable to have. An example might be an optionally used external cache chip also mounted on the same planar and used in conjunction with a processor chip. While one approach to obtaining better bandwidth between the processor and the cache would be to place both units on the same chip or combined into a multi-chip module (MCM), there may be strategic reasons for wanting to market the processor chip by itself as well as in combination with a given cache chip.

It would therefore be desirable to have an I/O configuration that would have an increased bandwidth between electronic chips that may optionally be combined on a planar.

### SUMMARY OF THE INVENTION

The present invention comprises providing an increase bandwidth connection between electronic chips mounted on a planar or other substrate.

### BRIEF DESCRIPTION OF THE DRAWINGS

For a more complete understanding of the present invention, and its advantages, reference will now be made in the following Detailed Description to the accompanying drawings, in which:

FIG. 1 is a top view of a pair of electronic chips mounted upon a substrate wherein circuitry and other components on the substrate are not specifically shown;

FIG. 2A is illustrative of one cross-sectional side view configuration of the chips of FIG. 1;

FIG. 2B is illustrative of a second possible cross-sectional side view configuration of the chips of FIG. 1;

FIG. 3 is a top view of a second pair of electronic chips mounted upon a substrate wherein circuitry and other components on the substrate are not specifically shown;

FIG. 4 is illustrative of a cross-sectional side view configuration of the chips of FIG. 3;

FIG. 5 is illustrative of a cross-sectional side view configuration of a plurality of subterranean chips interconnected to a superior or mother chip;

FIG. 6 is a cross-sectional view of a chip assembly where the mother and ancillary chips do not have to be of different sizes; and

FIG. 7 is a cross-sectional view of a chip assembly where the mother and ancillary chips are inverted in position from that of FIG. 2B to simplify the connections from the mother chip to the planar.

### DETAILED DESCRIPTION

It should be mentioned that multi-chip modules (MCMs), such as shown in U.S. Pat. No. 6,507,115 B2 assigned to the same assignee as the present invention are recognized as prior art. These MCMs are designed to be a composite unitary device and do not have optional connectivity in accordance with customer requirements. The teachings of U.S. Pat. No. 6,507,115 B2 are incorporated by reference herein for all purposes.

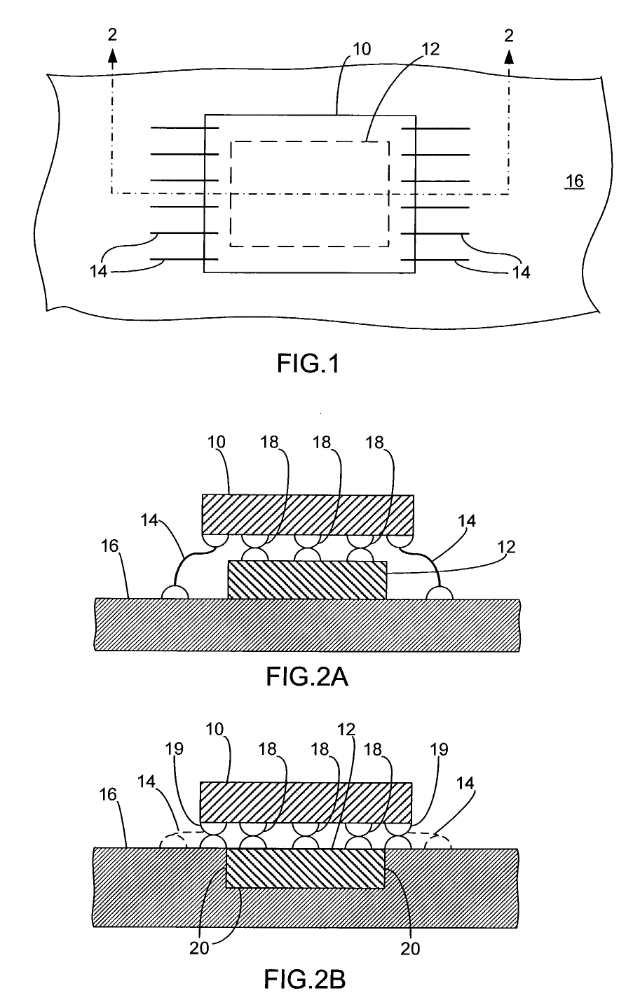

In FIG. 1, an electronic chip, device or die 10 is shown covering a second and smaller chip or die 12 shown by a dash line rectangle. Wires or connections 14 provide I/O (input/output) connections to a substrate or planar 16 (not shown). The chip 10 may be referred to as a superior or mother chip, especially when it is supplying the power to the second chip 12. Although further components or circuitry are not shown on the planar 16, the wires 14 would be used to connect the chip 10 to this other circuitry. Further, although the connections 14 are only shown on two sides of chip 10, they will, in many instances of chip mounting, extend completely around the periphery of chip 10.

In FIG. 2A, a cross-section of FIG. 1 shows the chips 10 and 12 mounted upon a substrate or planar 16. The wires 14 provide power to the chip 10 and allow the transmission of signals between other circuitry mounted on the planar 16 and chip 10. Protrusions, solder bumps or industry designated C4 structures designated as 18 act to permit the transmission of power and signals between chips 10 and 12. As will be realized, these protrusions are exaggerated in height for the purpose of illustration. Typically, the distance between chips 10 and 12, after the bonding of protrusions 18, will be very minimal. In some parts of the electronic industry, these connection protrusions are further termed “Z” connections. Since these Z connections are very short, the signal frequency bandwidth obtainable is much greater than can be obtained using the wires 14 and the associated electrical paths on the planar 16. Typically, the protrusions 18 are made to have a good electrical connection by placing the chips in correct alignment with one another and applying an amount of heat necessary to obtain a good bond therebetween. As will be realized, chip 10 thus has two sets of I/O connections. A first, peripheral or outer set of I/O connections are those placed where wires 14 interconnect protrusions on the chip 10 to circuitry on the planar 16. A second or inner set of connections, illustrated by protrusions 18, provide I/O connections to the chip 12. The connection of the wires 14 to the planar 16 may be to a protrusion such as shown or to a circuit path such as shown later in FIG. 7 or alternatively in the referenced patent.

In FIG. 2B, a cavity, having the sides and bottom labeled 20 is shown within the planar 16. The chip 12 is placed within the cavity 20 whereby the wires 14 are shorter than they would be in the simpler to manufacture configuration of FIG. 2A. In this configuration, the wires 14 are shown as dash lines, as they are optional. An alternative connection is shown using protrusions 19 to directly contact similar C4 protrusions on the planar 16.

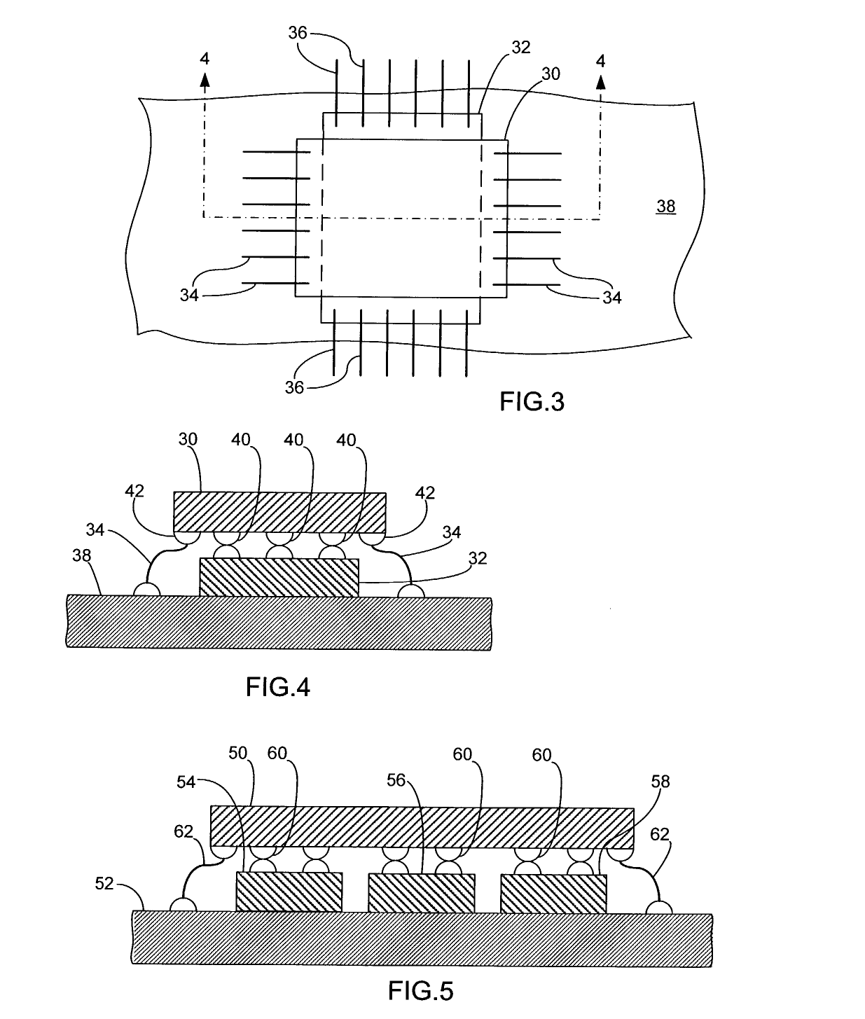

In FIG. 3, a chip 30 is positioned over a chip 32 to form a cross. The chip 30 is shown having I/O connections 34 going to a planar not shown in this figure. Chip 32 is shown having independent I/O connections 36 to the planar.

In FIG. 4, the chip 32 is illustrated on the surface of a planar 38 along with Z connections to the chip 30. For clarity, the connections 36 between the chip 32 and the planar are not shown. To reduce the length of the connections 34, the chip 32 can be placed in a recess of the planar 38 in the same manner as shown in FIG. 2B and may further use the direct connections from protrusions 42 to similar contacts placed on planar 38.

In FIG. 5, a mother chip 50 is mounted above a planar 52 and is interconnected to a plurality of chips 54, 56 and 58 by Z connections 60. The I/O is provided by wires 62. In a manner similar to that shown in FIG. 2B, cavities or recesses may be provided in planar 52 for placing the chips 54, 56 and 58 and thus reducing the length and increasing the bandwidth of signals passing through connections 62. As will be realized, in accordance with other considerations, the embodiment of FIG. 5 may include less than all of chips 54, 56 and 58. If the above assumption is used that the chip 50 is a processor, the ancillary chips may be assumed to provide varying quantities of cache. Alternatively, one of the ancillary chips, such as 58, might be used to provide enhanced functionality for processor 50 when the ancillary chip is used. An example of such enhanced functionality might be where chip 58 could provide increased floating point arithmetic capability to the processor on chip 50.

As shown in each of the side view figures, the upper chip has a set of peripheral I/O connections to the substrate upon which the chip is mounted as well as an inwardly disposed set of I/O connections for substantially direct connection to one or more ancillary chips.

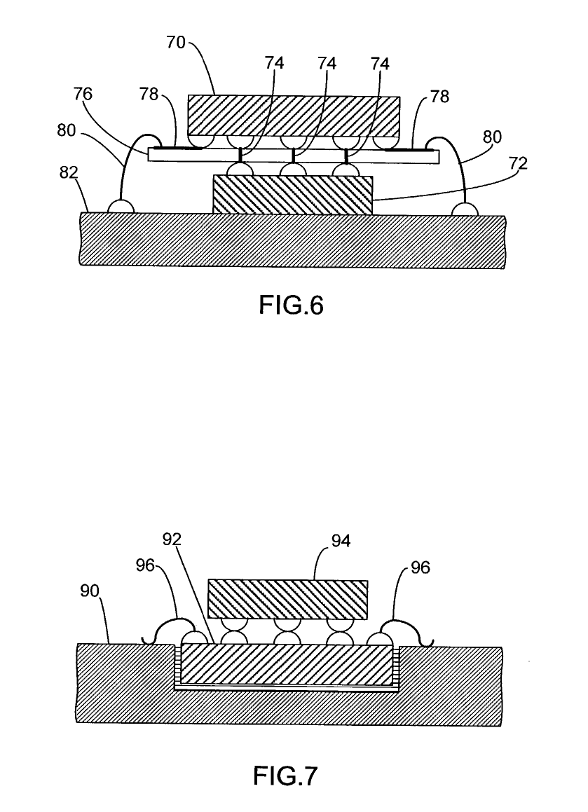

In FIG. 6, a mother chip 70 is shown connected to an ancillary chip 72 of the same physical size through vias 74 in a connection substrate 76. As known in the art, vias are merely connections from one side of a circuit board or substrate to the opposite side. Protrusions on the periphery of the chip 70 contact a conductive path 78 on substrate 76 and wires 80 are then bonded from the conductive path 78 to appropriate connections on a planar 82.

In FIG. 7, a recess (undesignated) is shown in a planar 90 and a mother chip 92 is placed in the recess. An ancillary chip 94 is electrically connected to the inwardly disposed I/O protrusions of chip 92, and wires 96 connect the outwardly disposed I/O protrusions of chip 92 to the planar 90. As may be observed, this assembly is essentially the inverse of FIG. 2B. It may be noticed, however, that an undesignated adhesive or other fill is used to position the die 92 solidly within the recess of planar 90.

In summary, the present invention illustrates a method of and apparatus for increasing the number of I/O ports of a given chip as well as increasing the bandwidth of signals passing between two optionally connected chips, such as 10 and 12 or those shown in FIGS. 3-7. The main or mother chip can advantageously be optionally connected to a plurality of other chips, such as shown in FIG. 5.

Although the invention has been described with reference to specific embodiments, the description is not meant to be construed in a limiting sense. Various modifications of the disclosed embodiments, as well as alternative embodiments of the invention, will become apparent to persons skilled in the art upon reference to the description of the invention. It is therefore contemplated that the claims will cover any such modifications or embodiments that fall within the true scope and spirit of the invention.

1. An integrated circuit chip assembly construction, comprising:
a superior chip having I/O circuitry on the periphery for connection to a substrate;
inwardly disposed I/O circuitry on a superior chip; and
an optionally connectable ancillary chip substantially directly connected to said superior chip via said inwardly disposed I/O circuitry.

2. A method of increasing the bandwidth of I/O integrated circuit die interconnections to an optional ancillary die on a planar, comprising:
providing I/O connection points on a surface of a first die;
providing corresponding 1/0 connection points on a surface of a second die;
aligning said first and second die to obtain contact between corresponding I/O connection points; and
applying an environment whereby an electrical connection is formed between corresponding connection points on said first and second die.

3. An integrated circuit assembly, comprising:
a substrate;
a first integrated circuit chip having a peripherally located set of I/O connections physically attached to corresponding circuitry on said substrate; and
an inwardly disposed set of I/O connections located on an exterior surface of said integrated circuit chip for optional connection to a further integrated circuit chip.

4. A method of increasing the bandwidth of I/O paths between a mother chip and an optional ancillary chip on a substrate, comprising:
providing a peripheral set of I/O connections an a chip for connection to a substrate; and
providing a set of C4 connections on said chip for optional direct connection to an ancillary chip.

5. An integrated circuit chip construction for use in a chip assembly, comprising:
a mother chip defining a periphery, said chip including:
first I/O circuitry at said periphery; and
second I/O circuitry disposed inwardly on said chip from said periphery; and
said mother chip operating in conjunction with a given ancillary chip via connections to said first I/O circuitry when both said mother chip and said ancillary chip are separately attached to a substrate; and
said mother chip providing enhanced operation due to increased I/O connection bandwidth when connected to said given ancillary chip via said second I/O circuitry.

6. An integrated circuit chip construction for use in a chip assembly, comprising:
a mother chip defining a periphery, said chip including:
first I/O circuitry at said periphery; and
second I/O circuitry disposed inwardly on said chip from said periphery; and
said mother chip being functionally operable in the absence of a given ancillary chip and said mother chip providing enhanced operation when connected to said given ancillary chip via said second I/O circuitry.
